(19) United States
(12) Patent Application Publication
(10) Pub. No.: US 2024/0244862 A1
(43) Pub. Date: Jul. 18, 2024

(54) LIGHT EMITTING DEVICE AND DISPLAY DEVICE INCLUDING THE SAME

(71) Applicant: SAMSUNG ELECTRONICS CO., LTD., Suwon-si (KR)

(72) Inventors: Jin A KIM, Suwon-si (KR); Ju Hyun KIM, Suwon-si (KR); Yuho WON, Suwon-si (KR); Won Sik YOON, Suwon-si (KR); Taehyung KIM, Suwon-si (KR); Hyunju KIM, Suwon-si (KR)

(21) Appl. No.: 18/405,428

(22) Filed: Jan. 5, 2024

(30) Foreign Application Priority Data
Jan. 6, 2023 (KR) 10-2023-0002531

(51) Int. Cl. H10K 50/115; C09K 11/02; C09K 11/06; H10K 85/30

(52) U.S. Cl. CPC H10K 50/115; C09K 11/02; C09K 11/06; H10K 85/381; H10K 2101/40

(57) ABSTRACT

A light emitting device includes a first electrode and a second electrode facing each other, a light emitting layer disposed between the first electrode and the second electrode, and the light emitting layer including quantum dots, wherein the light emitting layer includes a first light emitting layer proximate to the first electrode and a second light emitting layer proximate to the second electrode, the quantum dots of the first light emitting layer include a first ligand on a surface, and the quantum dots of the second light emitting layer include a second ligand on a surface, the first ligand different from the second ligand, a HOMO energy level of the first light emitting layer is lower (shallower) than a HOMO energy level of the second light emitting layer.

### CROSS-REFERENCE TO RELATED APPLICATION

This application claims priority to Korean Patent Application No. 10-2023-0002531 filed in the Korean Intellectual Property Office on Jan. 6, 2023, and all the benefits accruing therefrom under 35 U.S.C. § 119, the entire content of which is herein incorporated by reference.

### BACKGROUND

### 1. Field

A light emitting device and a display device including the light emitting device are disclosed.

### 2. Description of the Related Art

Quantum dots are a nanocrystal semiconductor material having a diameter of less than or equal to around 10 nm, and which exhibit quantum confinement effects. Quantum dots tend to emit light in a narrow wavelength region in comparison to commonly used phosphors. Quantum dots emit light as excited electrons transit from a conduction band to a valence band, and wavelengths of emitted light can be varied with a change of particle size of the quantum dots even of the same composition. Accordingly, quantum dots may emit light of a shorter wavelength with corresponding smaller particle size, and thus, quantum dots may provide light in a desirable wavelength region.

A light emitting layer including quantum dots, and various types of electronic devices including the quantum dots, are generally more efficient in terms of production costs compared to an organic light emitting diode using a light emitting layer including phosphorescent and/or fluorescent emitter materials, and as stated, desirable colors (wavelengths of light) may be emitted with a change in particle size of the quantum dots.

Luminous efficiency of the light emitting layer including quantum dots is determined by the quantum efficiency of the quantum dots, a balance of charge carriers (holes and electrons), light extraction efficiency, and the like. Particularly, in order to improve the quantum efficiency, the excitons formed by the combination of the charge carriers may be confined in the light emitting layer. However, if the excitons are not relatively confined within the light emitting layer due to various factors, the non-confinement of the excitons may lead to a problem of exciton quenching.

### SUMMARY

An embodiment provides a light emitting device that can achieve improved efficiency, life-span characteristics, voltage stability, and/or lower driving voltage.

Another embodiment provides a display device including the light emitting device.

According to an embodiment, a light emitting device includes a first electrode and a second electrode facing each other, and a light emitting layer disposed between the first electrode and the second electrode and including quantum dots,
wherein the light emitting layer includes a first light emitting layer proximate to the first electrode and a second light emitting layer proximate to the second electrode,
the quantum dots of the first light emitting layer include a first ligand on a surface of the quantum dots, and the quantum dots of the second light emitting layer include a second ligand on a surface of the quantum dots, and the first ligand is different from the second ligand, and
a HOMO energy level of the first light emitting layer is lower (shallower) than a HOMO energy level of the second light emitting layer.

A difference between the HOMO energy level of the first light emitting layer and the HOMO energy level of the second light emitting layer may be greater than or equal to about 0.1 electron volts (eV).

A LUMO energy level of the first light emitting layer may be lower (shallower) than a LUMO energy level of the second light emitting layer.

The first ligand may include an amine ligand, an amide ligand, an alkoxide ligand, a carboxylic acid ligand, or a combination thereof, and the second ligand may include a halogen-substituted carboxylic acid ligand, a halogen-substituted carboxylic acid ester ligand, a haloalkane ligand, a halogen ligand, or a combination thereof.

The amine ligand may be a compound represented by Chemical Formula 1.

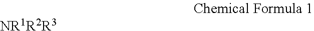

In Chemical Formula 1, R¹, R², and R³ are each independently hydrogen, deuterium, a substituted or unsubstituted C1 to C30 (e.g., C2 to C30, C3 to C30, C4 to C30, or C5 to C30) alkyl group, a substituted or unsubstituted C2 to C30 (e.g., C3 to C30, C4 to C30, or C5 to C30) alkenyl group, a substituted or unsubstituted C2 to C30 (e.g., C3 to C30, C4 to C30, or C5 to C30) alkynyl group, a substituted or unsubstituted C6 to C40 aryl group, a substituted or unsubstituted C3 to C40 heteroaryl group, or a combination thereof, or any two of R¹, R², or R³ are linked to each other to form an N-containing heterocycles, and R¹, R², and R³ are not all hydrogen or deuterium.

The amide ligand may be a compound represented by Chemical Formula 2.

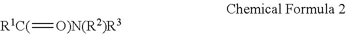

In Chemical Formula 2, R¹ and R³ are each independently hydrogen, deuterium, a substituted or unsubstituted C1 to C30 (e.g., C2 to C30, C3 to C30, C4 to C30, or C5 to C30) alkyl group, a substituted or unsubstituted C2 to C30 (e.g., C3 to C30, C4 to C30, or C5 to C30) alkenyl group, a substituted or unsubstituted C2 to C30 (e.g., C3 to C30, C4 to C30, or C5 to C30) alkynyl group, a substituted or unsubstituted C6 to C40 aryl group, a substituted or unsubstituted C3 to C40 heteroaryl group, or a combination thereof, and

R² is hydrogen, deuterium, a substituted or unsubstituted C1 to C30 (e.g., C2 to C30, C3 to C30, C4 to C30, or C5 to C30) alkyl group, a substituted or unsubstituted C2 to C30 (e.g., C3 to C30, C4 to C30, or C5 to C30) alkenyl group, a substituted or unsubstituted C2 to C30 (e.g., C3 to C30, C4 to C30, or C5 to C30) alkynyl group, a substituted or unsubstituted C6 to C40 aryl group, a substituted or unsubstituted C3 to C40 heteroaryl group, or a combination thereof.

The carboxylic acid ligand may be a compound represented by Chemical Formula 3.

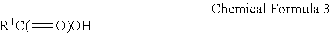

In Chemical Formula 3, R¹ is a substituted or unsubstituted C1 to C30 (e.g., C2 to C30, C3 to C30, C4 to C30, or C5 to C30) alkyl group, a substituted or unsubstituted C2 to C30 (e.g., C3 to C30, C4 to C30, or C5 to C30) alkenyl group, a substituted or unsubstituted C2 to C30 (e.g., C3 to C30, C4 to C30, or C5 to C30) alkynyl group, a substituted or unsubstituted C6 to C40 aryl group, a substituted or unsubstituted C3 to C40 heteroaryl group, or a combination thereof.

The halogen-substituted carboxylic acid ligand may be a compound represented by Chemical Formula 4.

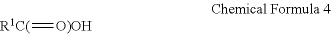

In Chemical Formula 4, R¹ is a substituted or unsubstituted C1 to C30 (e.g., C2 to C30, C3 to C30, C4 to C30, or C5 to C30) haloalkyl group, a substituted or unsubstituted C2 to C30 (e.g., C3 to C30, C4 to C30, or C5 to C30) haloalkenyl group, a substituted or unsubstituted C2 to C30 (e.g., C3 to C30, C4 to C30, or C5 to C30) haloalkynyl group, a substituted or unsubstituted C6 to C40 halogen-substituted aryl group, a substituted or unsubstituted C3 to C40 halogen-substituted heteroaryl group, or a combination thereof. The haloalkyl group may be a perfluoroalkyl group.

The halogen-substituted carboxylic acid ester ligand may be a compound represented by Chemical Formula 5.

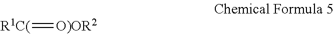

In Chemical Formula 4, R¹ and R² are each independently a substituted or unsubstituted C1 to C30 (e.g., C2 to C30, C3 to C30, C4 to C30, or C5 to C30) haloalkyl group, a substituted or unsubstituted C2 to C30 (e.g., C3 to C30, C4 to C30, or C5 to C30) haloalkenyl group, a substituted or unsubstituted C2 to C30 (e.g., C3 to C30, C4 to C30, or C5 to C30) haloalkynyl group, a substituted or unsubstituted C6 to C40 halogen-substituted aryl group, a substituted or unsubstituted C3 to C40 halogen-substituted heteroaryl group, or a combination thereof. The haloalkyl group may be a perfluoroalkyl group.

The first ligand may include a chloro-substituted or unsubstituted carboxylic acid ligand, a chloro-substituted or unsubstituted carboxylic acid ester ligand, a chloroalkane ligand, a chloride ligand, or a combination thereof, and the second ligand may include a fluoro-substituted carboxylic acid ligand, a fluoro-substituted carboxylic acid ester ligand, a fluoroalkane ligand, a fluoride ligand, or a combination thereof.

A content of the first ligand of the quantum dots in the first light emitting layer may be in the range of about 1 weight percent (wt %) to about 60 wt % based on a total amount (100 wt %) of ligand of the quantum dots in the first light emitting layer.

A content of the second ligand of the quantum dots in the second light emitting layer may be in the range of about 1 wt % to about 60 wt % based on a total amount (100 wt %) of the ligand of the quantum dots in the second light emitting layer.

The light emitting device may further include a third light emitting layer between the first light emitting layer and the second light emitting layer, and the HOMO energy level of the third light emitting layer may be between the HOMO energy level of the first light emitting layer and the HOMO energy level of the second light emitting layer.

The light emitting device includes a first charge auxiliary layer between the light emitting layer and the first electrode and a second charge auxiliary layer between the light emitting layer and the second electrode, and the HOMO energy levels of each layer of the first charge auxiliary layer, the first light emitting layer, the second light emitting layer, and the second charge auxiliary layer may sequentially increase or become sequentially deeper from the first charge auxiliary layer to the second charge auxiliary layer.

The quantum dots of the first light emitting layer and the quantum dots of the second light emitting layer may emit light of the same color, and a difference of peak emission wavelength of the quantum dots of the first and second light emitting layers may be less than or equal to about 15 nm, and the peak emission wavelength of the quantum dots of the first and second light emitting layers may have a full width at half maximum of less than or equal to about 40 nm.

The quantum dots of the light emitting layer may not include a heavy metal.

The respective quantum dots of the first and the second light emitting layers may further include an organic ligand in addition to the first and second ligands, respectively, and the organic ligand of the quantum dots of the first and the second light emitting layers may be independently RSH, R₃PO, R₃P, ROH, RCOOR, RPO(OH)₂, RHPOOH, R₂POOH, or a combination thereof (wherein R may each independently be selected from a substituted or unsubstituted C3 to C40 aliphatic hydrocarbon group, a substituted or unsubstituted C6 to C40 aromatic hydrocarbon group, or a combination thereof).

The first light emitting layer and the second light emitting layer may be configured to emit light of the same or different colors.

The second charge auxiliary layer may include a nanoparticle including a metal oxide.

The metal oxide may be a zinc metal oxide represented by Chemical Formula 6:

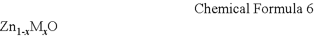

In Chemical Formula 6,

M is Mg, Ca, Zr, W, Li, Ti, Y, Al, or a combination thereof, and

0≤x≤0.5.

Another embodiment provides a display device including the aforementioned light emitting device.

The light emitting device can simultaneously improve efficiency, life-span, and voltage stability, and lower the driving voltage.

### BRIEF DESCRIPTION OF THE DRAWINGS

FIG. 1 is a schematic cross-sectional view of a light emitting device according to an embodiment.

FIG. 2 is a schematic cross-sectional view of a light emitting device according to an embodiment.

FIG. 3 is a schematic cross-sectional view of a light emitting device according to an embodiment.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein. Rather, these embodiments are provided so that this disclosure will be thorough and complete, and will fully convey the scope of the invention to those skilled in the art.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity of the example embodiments, and the same or similar constituent elements are indicated by the same reference numeral throughout the specification.

As used herein, “at least one of A, B, or C,” “one of A, B, C, or a combination thereof” and “one of A, B, C, and any combination thereof” refer to each constituent element, and any combination thereof (e.g., A; B; C; A and B; A and C; B and C; or A, B, and C).

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

As used herein, “sequentially” refers to a change in a content percentage of a compound, ligand, or group, or a change in a particular property or characteristic, of a material or layer, along a coordinate direction of the material or the layer. In an ordered structure of multiple layers the term “sequentially” also refers to a change in content of a compound, ligand, or group, or the particular characteristic or property, from one adjacent layer to the next layer. The change in content percentage, or change in character or property, may be step-wise, linear and continuous, non-linear and continuous, or a combination thereof.

As used herein, when a definition is not otherwise provided, the energy level is the highest occupied molecular orbital (HOMO) energy level or the lowest unoccupied molecular orbital (LUMO) energy level.

Hereinafter, a work function or a HOMO energy level is expressed as an absolute value from a vacuum level. In addition, when the work function or the HOMO energy level is referred to be “deep,” “high” or “large,” the work function or the HOMO energy level has a large absolute value based on “0 eV” of the vacuum level, while when the work function or the HOMO energy level is referred to be “shallow,” “low,” or “small,” the work function or HOMO energy level has a small absolute value based on “0 eV” of the vacuum level.

As used herein, when a definition is not otherwise provided, the HOMO energy level may be evaluated by the amount of photoelectrons emitted according to energy by irradiating UV light onto a thin film using AC-2 (Hitachi) or AC-3 (Riken Keiki Co., LTD.).

As used herein, when a definition is not otherwise provided, the LUMO energy level is obtained as follow: an energy bandgap is obtained using a UV-Vis spectrometer (Shimadzu Corporation), and then the LUMO energy level is calculated from the energy bandgap and the measured HOMO energy level.

As used herein, “Group” refers to a group of the Periodic Table.

As used herein, “Group II” refers to Group IIA and Group IIB, and examples of Group II metal may be Cd, Zn, Hg, and Mg, but are not limited thereto.

As used herein, “Group III” refers to Group IIIA and Group IIIB, and examples of Group III metal may be Al, In, Ga, and TI, but are not limited thereto.

As used herein, “Group IV” refers to Group IVA and Group IVB, and examples of a Group IV metal may be Si, Ge, and Sn, but are not limited thereto. As used herein, the term “metal” may include a semi-metal such as Si.

As used herein, “Group V” refers to Group VA, and examples may include nitrogen, phosphorus, arsenic, antimony, and bismuth, but are not limited thereto.

As used herein, “Group VI” refers to Group VIA, and examples may include sulfur, selenium, and tellurium, but are not limited thereto.

As used herein, when a definition is not otherwise provided, “substituted” refers to replacement of hydrogen of a compound, a group, or a moiety by a substituent selected from a C1 to C30 alkyl group, a C2 to C30 alkenyl group, a C2 to C30 alkynyl group, a C2 to C30 epoxy group, a C2 to C30 alkylacyloxy group, a C3 to C30 alkenylacyloxy group (e.g., acrylate group, methacrylate group, etc.), a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), and any combination thereof.

As used herein, when a definition is not otherwise provided, “alkyl group” may be a monovalent linear or branched saturated hydrocarbon group, for example a methyl group, an ethyl group, an n-propyl group, an isopropyl group, an n-butyl group, an isobutyl group, a sec-butyl group, a tert-butyl group, an n-pentyl group, an isopentyl group, a tert-pentyl group, a neopentyl group, a 1,2-dimethyl propyl group, an n-hexyl group, an isohexyl group, a 1,3-dimethylbutyl group, a 1-isopropyl propyl group, a 1,2-dimethylbutyl group, an n-heptyl group, a 1,4-dimethyl pentyl group, a 3-ethyl pentyl group, a 2-methyl-1-isopropyl propyl group, a 1-ethyl-3-methyl butyl group, an n-octyl group, a 2-ethylhexyl group, a 3-methyl-1-isopropyl butyl group, a 2-methyl-1-isopropyl butyl group, a 1-tert-butyl-2-methyl propyl group, an n-nonyl group, 3,5,5-trimethyl hexyl group, an n-decyl group, an isodecyl group, an n-undecyl group, a 1-methyldecyl group, an n-dodecyl group, an n-tridecyl group, an n-tetradecyl group, an n-pentadecyl group, an n-hexadecyl group, an n-heptadecyl group, an n-octadecyl group, a nonadecyl group, an icosyl group, and the like.

Here, “alkenyl (group)” refers to a linear or branched monovalent hydrocarbon group having one or more carbon-carbon double bonds.

Here, “alkynyl (group)” refers to a linear or branched monovalent hydrocarbon group having one or more carbon-carbon triple bonds.

As used herein, when a definition is not otherwise provided, “alkoxy (group)” may be a functional group represented by —OR, wherein R is a monovalent linear or branched saturated hydrocarbon group, for example a methyl group, an ethyl group, an n-propyl group, an isopropyl group, an n-butyl group, an isobutyl group, a sec-butyl group, a tert-butyl group, an n-pentyl group, an isopentyl group, a tert-pentyl group, a neopentyl group, a 1,2-dimethyl propyl group, an n-hexyl group, an isohexyl group, a 1,3-dimethylbutyl group, a 1-isopropyl propyl group, a 1,2-dimethylbutyl group, an n-heptyl group, a 1,4-dimethyl pentyl group, a 3-ethyl pentyl group, a 2-methyl-1-isopropyl propyl group, a 1-ethyl-3-methyl butyl group, an n-octyl group, a 2-ethylhexyl group, a 3-methyl-a 1-isopropyl butyl group, a 2-methyl-1-isopropyl butyl group, a 1-tert-butyl-2-methyl propyl group, an n-nonyl group, a 3,5,5-trimethyl hexyl group, an n-decyl group, an isodecyl group, an n-undecyl group, a 1-methyldecyl group, an n-dodecyl group, an n-tridecyl group, an n-tetradecyl group, an n-pentadecyl group, an n-hexadecyl group, an n-heptadecyl group, an n-octadecyl group, a nonadecyl group, an icosyl group, and the like.

As used herein, when a definition is not otherwise provided, “alkoxide” refers to a compound having the alkoxy group.

Herein, “hydrocarbon group” refers to a group including carbon and hydrogen (e.g., alkyl group, alkenyl group, alkynyl group, or aryl group). The hydrocarbon group may be a group having a monovalence or greater formed by removal of one or more hydrogen atoms from, alkane, alkene, alkyne, or arene. In the hydrocarbon group, at least one methylene may be replaced by —O—, —C(═O)—, —C(═O)O—, —OC(═O)—, —NH—, or a combination thereof.

Herein, “aryl” refers to a group formed by removal of at least one hydrogen from an arene (e.g., phenyl group or naphthyl group).

Herein, the “alkane” compound may be a C1 to C30 (e.g., C2 to C30, C3 to C30, C4 to C30, or C5 to C30) hydrocarbon compound.

Herein, “hetero” refers to one including 1 to 3 heteroatoms of N, O, S, Si, P, or a combination thereof.

As used herein, when a definition is not otherwise provided, “combination thereof” in the definition of chemical formula refers to at least two substituents bound to each other by a single bond or a C1 to C10 alkylene group, or at least two fused substituents. In addition, hereinafter, when a definition is not otherwise provided, “combination” may refer to a mixture of two or more, an alloy of two or more, and a stacked structure of two or more.

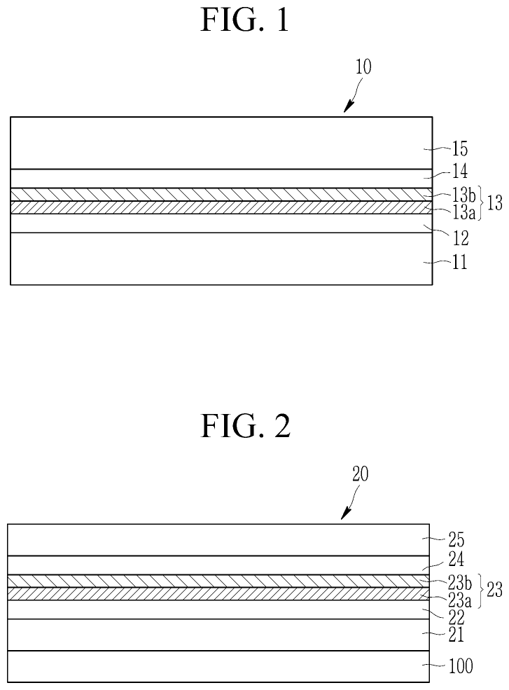

Hereinafter, a light emitting device according to an embodiment will be described with reference to FIG. 1.

FIG. 1 is a schematic cross-sectional view of a light emitting device according to an embodiment.

Referring to FIG. 1, a light emitting device 10 according to an embodiment includes a first electrode 11 and a second electrode 15 facing each other, a light emitting layer 13 disposed between the first electrode 11 and the second electrode 15 and including a first light emitting layer 13a and a second light emitting layer 13b, a first charge auxiliary layer 12 disposed between the light emitting layer 13 and the first electrode 11, and a second charge auxiliary layer 14 disposed between the light emitting layer 13 and the second electrode 15. Herein, at least one of the first charge auxiliary layer 12 and the second charge auxiliary layer 14 may be omitted.

One of the first electrode 11 and the second electrode 15 may be an anode and the other may be a cathode. For example, the first electrode 11 may be an anode and the second electrode 15 may be a cathode.

The first electrode 11 may be made of a conductor, for example a metal, a conductive metal oxide, or a combination thereof. The first electrode 11 may be for example made of a metal such as nickel, platinum, vanadium, chromium, copper, zinc, gold, or an alloy thereof; a conductive metal oxide such as zinc oxide, indium oxide, tin oxide, indium tin oxide (ITO), indium zinc oxide (IZO), or fluorine doped tin oxide; or a combination of a metal and an oxide such as ZnO and Al or SnO₂ and Sb, but is not limited thereto. In an embodiment, the first electrode may include a transparent conductive metal oxide, for example, indium tin oxide. A work function of the first electrode may be higher than a work function of the second electrode that will be described later. A work function of the first electrode may be lower than a work function of the second electrode that will be described later.

The second electrode 15 may be made of a conductor, for example a metal, a conductive metal oxide, and/or a conductive polymer. The second electrode 15 may be for example made of a metal such as aluminum, magnesium, calcium, sodium, potassium, titanium, indium, yttrium, lithium, gadolinium silver, gold, platinum, tin, lead, cesium, or barium, or an alloy thereof; a conductive metal oxide such as zinc oxide, indium oxide, tin oxide, indium tin oxide (ITO), indium zinc oxide (IZO), or fluorine doped tin oxide; a multi-layered structure material such as LiF/Al, LiO₂/Al, Liq/Al, LiF/Ca, and BaF₂/Ca, but is not limited thereto.

In an embodiment, the work function of the first electrode 11 may be for example about 4.5 eV to about 5.0 eV (e.g., about 4.6 eV to about 4.9 eV) and the work function of the second electrode 15 may be for example greater than or equal to about 4.0 eV and less than about 4.5 eV (e.g., about 4.0 eV to about 4.3 eV). A work function of the first electrode may be higher than a work function of the second electrode. In an embodiment, the work function of the second electrode 15 may be for example about 4.5 eV to about 5.0 eV (e.g., about 4.6 eV to about 4.9 eV) and the work function of the first electrode 11 may be for example greater than or equal to about 4.0 eV and less than about 4.5 eV (e.g., about 4.0 eV to about 4.3 eV). A work function of the first electrode 11 may be lower than a work function of the second electrode 15.

At least one of the first electrode 11 and the second electrode 15 may be a light-transmitting electrode, and the light-transmitting electrode may be for example made of a conductive oxide such as zinc oxide, indium oxide, tin oxide, indium tin oxide (ITO), indium zinc oxide (IZO), or fluorine doped tin oxide, or a metal thin layer of a single layer or a multilayer. When one of the first electrode 11 and the second electrode 15 is a non-light-transmitting electrode, it may be made of for example an opaque conductor such as aluminum (Al), silver (Ag), or gold (Au).

Thicknesses of the first electrode 11 and the second electrode 15 are not particularly limited and may be appropriately selected considering device efficiency. For example, the thicknesses of the first electrode 11 and the second electrode 15 may be greater than or equal to about 5 nm, for example, greater than or equal to about 50 nm. For example, the thicknesses of the first electrode 11 and the second electrode 15 may be less than or equal to about 100 micrometers (μm), for example, less than or equal to about 10 μm, less than or equal to about 1 μm, less than or equal to about 900 nm, less than or equal to about 500 nm, or less than or equal to about 100 nm.

The light emitting layer 13 includes a first light emitting layer 13a in contact with the first charge auxiliary layer 12 and a second light emitting layer 13b disposed on the first light emitting layer 13a. The first light emitting layer 13a, and the second light emitting layer 13b, each include quantum dots, and the quantum dots include different ligands on their respective surfaces.

The quantum dots may realize high color reproducibility and may draw attention as a next-generation display material in terms of forming a light emitting layer in a solution process. Colloid synthesized quantum dots may include organic ligands (e.g., organic compounds including long-chain aliphatic hydrocarbon and a functional group, such as oleic acid (OA)) on the surfaces of the quantum dots. The organic ligand is necessary to ensure dispersibility of the quantum dots in matrix mediums, but it may interfere with charge flows in the quantum dots formed as a monolayer. Accordingly, it may be difficult to appropriately balance the electrons/holes in the electroluminescent device within the light emitting layer. For example, when a flow of positive charges (holes) relative to negative charges (electrons) is limited in the light emitting layer 13 quantum dots, a light emitting region may be formed not inside the light emitting layer, but instead, on or near an interface between a hole auxiliary layer (e.g., hole transport layer) and the light emitting layer, and excitons produced on or near the interface may be easily quenched, which may have a negative influence on device efficiency. Particularly, extra electrons not recombined on or near the interface due to high LUMO energy of QD in QD-LED emitting blue light may move toward the hole transport layer, and the device efficiency may be more severely deteriorated.

Accordingly, the light emitting device 10 according to an embodiment has first and second light emitting layers 13a and 13b in the light emitting layer 13, wherein the quantum dots of the first light emitting layer 13a include a first ligand on the surface, and the quantum dots of the second light emitting layer 13b include a second ligand on the surface, the first ligand being different from the second ligand. By including different ligands on the quantum dots of the first and the second light emitting layers, the HOMO energy level of the first light emitting layer 13a is adjusted to be lower (shallower) than the HOMO energy level of the second light emitting layer 13b. The ligand contained in the first and second light emitting layers 13a and 13b may directly affect the hole (or charge) transport ability of the first and second light emitting layers 13a and 13b. When the HOMO energy levels in the first and second light emitting layers 13a and 13b are adjusted as described above, electron-hole recombination can be more readily formed at or near the center of the light emitting layer 13. As a result, charge flow within the light emitting layer 13 can be controlled to exhibit improved electroluminescence properties and extended life-span characteristics. Although not intended to be bound by a specific theory, in the device according to an embodiment, the aforementioned structure allows the emission region generated by recombination of electrons and holes to be expanded and induces the emission region to be formed at or near the center of the light emitting layer 13. This can result in improved electroluminescence properties (efficiency and luminance) for the device.

The first light emitting layer 13a may have a HOMO energy level of greater than or equal to about 5.4 eV, greater than or equal to about 5.5 eV, or greater than or equal to about 5.6 eV. The HOMO energy level of the first light emitting layer 13a may be less than or equal to about 6.9 eV, less than or equal to about 6.8 eV, less than or equal to about 6.7 eV, less than or equal to about 6.6 eV, less than or equal to about 6.5 eV, less than or equal to about 6.4 eV, less than or equal to about 6.3 eV, less than or equal to about 6.2 eV, less than or equal to about 6.1 eV, less than or equal to about 6.0 eV, less than about 6.0 eV, less than or equal to about 5.9 eV, or less than or equal to about 5.8 eV. In an embodiment, the first light emitting layer 13a may have a HOMO energy level of about 5.4 eV to about 6.9 eV, about 5.4 eV to about 6.6 eV, about 5.4 eV to about 6.3 eV, about 5.5 eV to about 6.9 eV, about 5.5 eV to about 6.6 eV, about 5.5 eV to about 6.3 eV, about 5.6 eV to about 6.9 eV, about 5.6 eV to about 6.6 eV, or about 5.6 eV to about 6.3 eV.

The second light emitting layer 13b may have a HOMO energy level of greater than or equal to about 5.5 eV, greater than or equal to about 5.6 eV, greater than or equal to about 5.7 eV, greater than or equal to about 5.8 eV, greater than or equal to about 5.9 eV, greater than or equal to about 6.0 eV, greater than or equal to about 6.1 eV, or greater than or equal to about 6.2 eV. The HOMO energy level of the second light emitting layer 13b may be less than or equal to about 7.0 eV, less than or equal to about 6.9 eV, less than or equal to about 6.8 eV, less than or equal to about 6.7 eV, less than or equal to about 6.6 eV, less than or equal to about 6.5 eV, less than or equal to about 6.4 eV, or less than or equal to about 6.3 eV. In an embodiment, the second light emitting layer 13b may have a HOMO energy level of about 5.5 eV to about 7.0 eV, about 5.7 eV to about 6.8 eV, about 5.7 eV to about 7.0 eV, about 5.9 eV to about 6.8 eV, or about 5.9 eV to about 6.5 eV.

In an embodiment, a difference between the HOMO energy level of the first emitting layer 13a and the HOMO energy level of the second emitting layer 13b may be greater than or equal to about 0.1 eV, for example, greater than about 0.1 eV, greater than or equal to about 0.2 eV, greater than or equal to about 0.3 eV, greater than or equal to about 0.4 eV, greater than or equal to about 0.5 eV, greater than or equal to about 0.6 eV, greater than or equal to about 0.7 eV, greater than or equal to about 0.8 eV, greater than or equal to about 0.9 eV, or greater than or equal to about 1.0 eV. Additionally, the difference between the HOMO energy level of the first light emitting layer 13a and the HOMO energy level of the second light emitting layer 13b may be less than or equal to about 1.5 eV, for example, less than or equal to about 1.4 eV, less than or equal to about 1.3 eV, or less than or equal to about 1.2 eV.

The LUMO energy level of the first light emitting layer 13a may be higher than the LUMO energy level of the second light emitting layer 13b. As a result, the charge flow within the light emitting layer 13 can be controlled so that the emission region is located at or near the center of the light emitting layer 13, thereby improving the performance of the device.

The first light emitting layer 13a may have a LUMO energy level of less than or equal to about 3.9 eV, for example, less than or equal to about 3.8 eV, less than or equal to about 3.7 eV, less than or equal to about 3.6 eV, less than or equal to about 3.5 eV, less than or equal to about 3.4 eV, less than or equal to about 3.3 eV, less than or equal to about 3.2 eV, less than or equal to about 3.1 eV, less than or equal to about 3.0 eV, less than or equal to about 2.9 eV, or less than or equal to about 2.8 eV. The LUMO energy level of the first light emitting layer 13a may be greater than or equal to about 2.4 eV, for example, greater than or equal to about 2.5 eV, greater than or equal to about 2.6 eV, or greater than or equal to about 2.7 eV.

The second light emitting layer 13b may have a LUMO energy level of, for example, less than or equal to about 4.0 eV, less than or equal to about 3.9 eV, less than or equal to about 3.8 eV, for example, less than or equal to about 3.7 eV, less than or equal to about 3.6 eV, or less than or equal to about 3.5 eV. The LUMO energy level of the second light emitting layer 13b may be greater than or equal to about 2.6 eV, greater than or equal to about 2.7 eV, greater than or equal to about 2.8 eV, greater than or equal to about 2.9 eV, greater than or equal to about 3.0 eV, greater than or equal to about 3.1 eV, greater than or equal to about 3.2 eV, or greater than or equal to about 3.3 eV.

A difference between the LUMO energy level of the first light emitting layer 13a and the LUMO energy level of the second light emitting layer 13b may be greater than or equal to about 0.1 eV, for example, greater than about 0.1 eV, greater than or equal to about 0.2 eV, greater than or equal to about 0.3 eV, greater than or equal to about 0.4 eV, greater than or equal to about 0.5 eV, greater than or equal to about 0.6 eV, greater than or equal to about 0.7 eV, greater than or equal to about 0.8 eV, greater than or equal to about 0.9 eV, or greater than or equal to about 1.0 eV. Additionally, the difference between the LUMO energy level of the first light emitting layer 13a and the LUMO energy level of the second light emitting layer 13b may be less than or equal to about 1.5 eV, for example, less than or equal to about 1.4 eV, less than or equal to about 1.3 eV, or less than or equal to about 1.2 eV.

The light emitting layer 13 may include (e.g., a plurality of) quantum dot(s). The quantum dots are nano-sized semiconductor nanocrystal particles and may exhibit quantum confinement effects. The quantum dots may include a Group II-VI compound, a Group III-V compound, a Group IV-VI compound, a Group IV element or compound, a Group I-III-VI compound, a Group II-III-VI compound, a Group I-II-IV-VI compound, or a combination thereof.

The Group II-VI compound may be selected from a binary element compound selected from CdSe, CdTe, ZnS, ZnSe, ZnTe, ZnO, HgS, HgSe, HgTe, MgSe, MgS, and a mixture thereof; a ternary element compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group II-VI compound may further include a Group III metal.

The Group III-V compound may be selected from a binary element compound selected from GaN, GaP, GaAs, GaSb, AlN, AlP, AlAs, AlSb, InN, InP, InAs, InSb, and a mixture thereof; a ternary element compound selected from GaNP, GaNAs, GaNSb, GaPAs, GaPSb, AlNP, AlNAs, AlNSb, AlPAs, AlPSb, InNP, InNAs, InNSb, InPAs, InPSb, and a mixture thereof; and a quaternary element compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The Group III-V compound may further include a Group II metal (e.g., InZnP).

The Group IV-VI compound may be selected from a binary element compound selected from SnS, SnSe, SnTe, PbS, PbSe, PbTe, and a mixture thereof; a ternary element compound selected from SnSeS, SnSeTe, SnSTe, PbSeS, PbSeTe, PbSTe, SnPbS, SnPbSe, SnPbTe, and a mixture thereof; and a quaternary element compound selected from SnPbSSe, SnPbSeTe, SnPbSTe, and a mixture thereof. Examples of the Group I-III-VI compound may include CuInSe₂, CuInS₂, CuInGaSe, and CuInGaS, but are not limited thereto. Examples of the Group I-II-IV-VI compound may include CuZnSnSe and CuZnSnS, but are not limited thereto. The Group IV element or compound may be selected from a single element selected from Si, Ge, and a mixture thereof; and a binary element compound selected from SiC, SiGe, and a mixture thereof.

In an embodiment, the quantum dots of the light emitting layer 13 may not include a heavy metal (e.g., cadmium, lead, mercury, or all of them). As used herein, “not including a heavy metal” refers to including the heavy metal substantially, for example, in an amount of less than about 100 parts per million (ppm), less than about 50 ppm, less than about 30 ppm, or less than about 20 ppm. The quantum dots may include, for example, semiconductor nanocrystals including a Group III-V compound including indium and phosphorus. The Group III-V compound may further include zinc. The quantum dot may include a semiconductor nanocrystal including a Group II-VI compound including a chalcogen element (e.g., sulfur, selenium, tellurium, or a combination thereof) and zinc.

In the quantum dots, the aforementioned binary element compound, ternary element compound, and/or quaternary element compound respectively exists in a uniform concentration in the particle or in partially different concentrations in the same particle. The semiconductor nanocrystals may have a core/shell structure wherein a first semiconductor nanocrystal (core) is surrounded by another second semiconductor nanocrystal (shell) having a different composition. In an embodiment, the quantum dots may include a core including the aforementioned compounds (i.e., Group II-VI compound, Group III-V compound, Group IV-VI compound, Group IV element or compound, Group I-III-VI compound, Group II-III-VI compound, Group I-II-IV-VI compound, or a combination thereof) and a shell having a different composition from the core and including the aforementioned compounds. The core may include InP, InZnP, ZnSe, ZnSeTe, or a combination thereof. The shell may include InP, InZnP, ZnSe, ZnS, ZnSeTe, ZnSeS, or a combination thereof. The shell may include a multi-layered shell having at least two layers. The shell may include Zn, Se, and optionally S (e.g., directly) on the core. The shell may include zinc and sulfur in the outermost layer.

The core and the shell may have a concentration gradient wherein the concentration of the element(s) of the shell decreases toward the core. In addition, the semiconductor nanocrystals may have a structure including one semiconductor nanocrystal core and multi-layered shell surrounding the core. Herein, the multi-layered shell structure has a structure of two or more layers and each layer may have a single composition or an alloy or may have a concentration gradient.

In the quantum dots, the shell material and the core material may have different energy bandgaps from each other. For example, the energy bandgap of the shell material may be greater than that of the core material. According to an embodiment, the energy bandgap of the shell material may be less than that of the core material. The quantum dot may have a multi-layered shell. In the multi-layered shell, the energy bandgap of the outer layer may be greater than the energy bandgap of the inner layer (i.e., the layer nearer to the core). In the multi-layered shell, the energy bandgap of the outer layer may be less than the energy bandgap of the inner layer.

In an embodiment, the quantum dots may include a core including a first semiconductor nanocrystal including indium, phosphorus, and optionally zinc and a shell disposed on the core and including a second semiconductor nanocrystal including zinc and a chalcogen element. In an embodiment, the quantum dots may include a core including a first semiconductor nanocrystal including zinc, selenium, and optionally tellurium and a shell disposed on the core and including a second semiconductor nanocrystal including zinc and a chalcogen element.

The quantum dots may have a particle size of greater than or equal to about 1 nm and less than or equal to about 100 nm. The quantum dots may have a particle size of about 1 nm to about 20 nm, for example, greater than or equal to about 2 nm, greater than or equal to about 3 nm, or greater than or equal to about 4 nm and less than or equal to about 50 nm, less than or equal to about 40 nm, less than or equal to about 30 nm, less than or equal to about 20 nm, less than or equal to about 15 nm, less than or equal to about 10 nm, less than or equal to about 9 nm, or less than or equal to about 8 nm. Shapes of the quantum dots are not particularly limited. For example, the shapes of the quantum dots may be a sphere, a polyhedron, a pyramid, a multi-pod, a cube, a rectangular parallelepiped, a nanotube, a nanorod, a nanowire, a nanosheet, or a combination thereof, but is not limited thereto.

The aforementioned quantum dots may be commercially available or appropriately synthesized.

As described above, in the light emitting device 10 according to an embodiment, the quantum dots present in the first and second light emitting layers 13a and 13b have different ligands (first ligand, second ligand) on the surface, thereby adjusting the HOMO energy levels.

The first ligand may include an amine ligand, an amide ligand, an alkoxide ligand, a carboxylic acid ligand, or a combination thereof.

The amine ligand may be a compound represented by Chemical Formula 1.

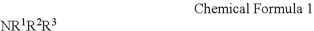

In Chemical Formula 1, R¹, R², and R³ are each independently hydrogen, deuterium, a substituted or unsubstituted C1 to C30 (e.g., C2 to C30, C3 to C30, C4 to C30, or C5 to C30) alkyl group, a substituted or unsubstituted C2 to C30 (e.g., C3 to C30, C4 to C30, or C5 to C30) alkenyl group, a substituted or unsubstituted C2 to C30 (e.g., C3 to C30, C4 to C30, or C5 to C30) alkynyl group, a substituted or unsubstituted C6 to C40 aryl group, a substituted or unsubstituted C3 to C40 heteroaryl group, or a combination thereof, or any two of R¹, R², or R³ are linked to each other to form an N-containing heterocycles, and R¹, R², and R³ are not all hydrogen or deuterium.

The amine ligand may be an alkyl amine ligand, (hetero)arylamine ligand, alkyl (hetero)arylamine ligand, (hetero)arylalkylamine ligand, N-containing heterocyclic ligand, etc.

Specific examples of the alkyl amine may include pentylamine, hexylamine, heptylamine, octylamine, nonylamine, decylamine, undecylamine, dodecylamine, tridecylamine, pentadecylamine, hexadecylamine, heptadecylamine, octadecylamine, nonadecylamine, oleylamine, or a combination thereof.

Specific examples of the (hetero)arylamine may include phenylamine, naphthylamine, aminodiphenylamine, methylene dianiline, toluenediamine, phenylenediamine, phenyl pyridinediamine, pyridinepyrimidinediamine, naphthylphenylamine, phenylpyrimidinediamine, or a combination thereof.

Specific examples of the N-containing heterocyclic ligand may include phenothiazine, phenoxazine, quinoline, imidazole, benzimidazole, or a derivative thereof.

The amide ligand may be a compound represented by Chemical Formula 2.

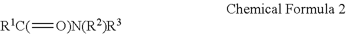

In Chemical Formula 2, R¹ and R³ are each independently hydrogen, deuterium, a substituted or unsubstituted C1 to C30 (e.g., C2 to C30, C3 to C30, C4 to C30, or C5 to C30) alkyl group, a substituted or unsubstituted C2 to C30 (e.g., C3 to C30, C4 to C30, or C5 to C30) alkenyl group, a substituted or unsubstituted C2 to C30 (e.g., C3 to C30, C4 to C30, or C5 to C30) alkynyl group, a substituted or unsubstituted C6 to C40 aryl group, a substituted or unsubstituted C3 to C40 heteroaryl group, or a combination thereof, and

R² is hydrogen, deuterium, a substituted or unsubstituted C1 to C30 (e.g., C2 to C30, C3 to C30, C4 to C30, or C5 to C30) alkyl group, a substituted or unsubstituted C2 to C30 (e.g., C3 to C30, C4 to C30, or C5 to C30) alkenyl group, a substituted or unsubstituted C2 to C30 (e.g., C3 to C30, C4 to C30, or C5 to C30) alkynyl group, a substituted or unsubstituted C6 to C40 aryl group, a substituted or unsubstituted C3 to C40 heteroaryl group, or a combination thereof.

The alkoxide ligand refers to a compound in which at least one hydrogen of an alkane compound is substituted with an alkoxy group, and the alkoxy group may be a substituted or unsubstituted linear or branched C1 to C30 (e.g., C2 to C30, C3 to C30, C4 to C30, or C5 to C30) alkoxy group. The alkoxy group may be, for example, a methoxy group, an ethoxy group, a propoxy group, an isopropoxy group, a butoxy group, a pentyloxy group, a hexyloxy group, a heptyloxy group, an octyloxy group, a nonyloxy group, a decyloxy group, an undecyloxy group, a dodecyloxy group, a tridecyloxy group, a tetradecyloxy group, a pentadecyloxy group, a hexadecyloxy group, a heptadecyloxy group, an octadecyloxy group, a 2-ethylhexyloxy group, a 3-ethylpentyloxy group, and the like.

The carboxylic acid ligand may be a compound represented by Chemical Formula 3.

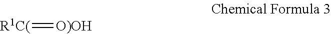

In Chemical Formula 3, R¹ is a substituted or unsubstituted C1 to C30 (e.g., C2 to C30, C3 to C30, C4 to C30, or C5 to C30) alkyl group, a substituted or unsubstituted C2 to C30 (e.g., C3 to C30, C4 to C30, or C5 to C30) alkenyl group, a substituted or unsubstituted C2 to C30 (e.g., C3 to C30, C4 to C30, or C5 to C30) alkynyl group, a substituted or unsubstituted C6 to C40 aryl group, a substituted or unsubstituted C3 to C40 heteroaryl group, or a combination thereof.

The carboxylic acid ligands may include pentanoic acid, hexanoic acid, heptanoic acid, octanoic acid, nonanoic acid, decanoic acid, undecanoic acid, dodecanoic acid, tridecanoic acid, pentadecanoic acid, hexadecanoic acid, heptadecanoic acid, octadecanoic acid, nonadecanoic acid, eicosanoic acid, heneicosanoic acid, docosanoic acid, trichosanoic acid, tetracosanoic acid, pentacosanoic acid, hexacosanoic acid, heptacosanoic acid, octacosanoic acid, nonacosanoic acid, triaconanoic acid, tetratriaconic acid, pentatriaconic acid, hexatriaconic acid, alpha-linolenic acid, eicosapentaenoic acid, docosahexaenoic acid, linoleic acid, gamma-linolenic acid, dihomo-gammalinolenic acid, arachidonic acid, paulinic acid, oleic acid, elaidic acid, erucic acid, nervonic acid, or a combination thereof.

The second ligand may include a halogen-substituted carboxylic acid ligand, a halogen-substituted carboxylic acid ester ligand, a haloalkane ligand, a halogen ligand, or a combination thereof.

The halogen-substituted carboxylic acid ligand may be a compound represented by Chemical Formula 4.

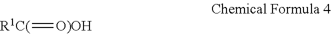

In Chemical Formula 4, R¹ is a substituted or unsubstituted C1 to C30 (e.g., C2 to C30, C3 to C30, C4 to C30, or C5 to C30) haloalkyl group, a substituted or unsubstituted C2 to C30 (e.g., C3 to C30, C4 to C30, or C5 to C30) haloalkenyl group, a substituted or unsubstituted C2 to C30 (e.g., C3 to C30, C4 to C30, or C5 to C30) haloalkynyl group, a substituted or unsubstituted C6 to C40 halogen-substituted aryl group, a substituted or unsubstituted C3 to C40 halogen-substituted heteroaryl group, or a combination thereof. The haloalkyl group may be a perfluoroalkyl group, and in this case, the ligand represented by Chemical Formula 4 may be a perfluoroalkanoic acid.

The halogen-substituted carboxylic acid ligand may include a compound in which at least one hydrogen of a carboxylic acid is substituted with a halogen. The halogen-substituted carboxylic acid ligand may be a halogen-substituted pentanoic acid, hexanoic acid, heptanoic acid, octanoic acid, nonanoic acid, decanoic acid, undecanoic acid, dodecanoic acid, tridecanoic acid, pentadecanoic acid, hexadecanoic acid, heptadecanoic acid, octadecanoic acid, nonadecanoic acid, eicosanoic acid, heneicosanoic acid, docosanoic acid, trichosanoic acid, tetracosanoic acid, pentacosanoic acid, hexacosanoic acid, heptacosanoic acid, heptacosanoic acid, octacosanoic acid, nonacosanoic acid, triaconic acid, tetratriaconic acid, pentatriaconic acid, hexatriaconic acid, alpha-linolenic acid, eicosapentaenoic acid, docosahexaenoic acid, linoleic acid, gamma-linolenic acid, dihomo-gammalinolenic acid, arachidonic acid, paulinic acid, oleic acid, elaidic acid, erucic acid, nervonic acid, or a combination thereof.

The halogen-substituted carboxylic acid ester ligand may be a compound represented by Chemical Formula 5.

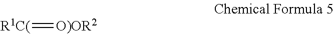

In Chemical Formula 5, R¹ and R² are each independently a substituted or unsubstituted C1 to C30 (e.g., C2 to C30, C3 to C30, C4 to C30, or C5 to C30) haloalkyl group, a substituted or unsubstituted C2 to C30 (e.g., C3 to C30, C4 to C30, or C5 to C30) haloalkenyl group, a substituted or unsubstituted C2 to C30 (e.g., C3 to C30, C4 to C30, or C5 to C30) haloalkynyl group, a substituted or unsubstituted C6 to C40 halogen-substituted aryl group, a substituted or unsubstituted C3 to C40 halogen-substituted heteroaryl group, or a combination thereof. The haloalkyl group may be a perfluoroalkyl group, and in this case, the ligand represented by Chemical Formula 5 may be a perfluoroalkanoic acid ester.

The haloalkane ligand means that at least one hydrogen of an alkane compound is substituted with a halogen.

The halogen may be F, Cl, Br or I.

In an embodiment, the first ligand may include a chloro-substituted or unsubstituted carboxylic acid ligand, a chloro-substituted or unsubstituted carboxylic acid ester ligand, a chloroalkane ligand, a chloride ligand, or a combination thereof, and the second ligand may include a fluoro-substituted carboxylic acid ligand, a fluoro-substituted carboxylic acid ester ligand, a fluoroalkane ligand, a fluoride ligand, or a combination thereof.

The quantum dots of the first light emitting layer 13a and the quantum dots of the second light emitting layer 13b may further include an organic ligand in addition to the first and second ligands, respectively. The organic ligand may independently include RSH, R₃PO, R₃P, ROH, RCOOR, RPO(OH)₂, RHPOOH, R₂POOH, or a combination thereof, wherein R is independently a substituted or unsubstituted C1 (C2, C3, or C5) to C40 aliphatic hydrocarbon group such as a substituted or unsubstituted C1 (C2, C3, or C5) to C40 alkyl or C2 (C3 or C5) to C40 alkenyl, a substituted or unsubstituted C6 to C40 aromatic hydrocarbon group such as a substituted or unsubstituted C6 to C40 aryl group, or a combination thereof.

Examples of the organic ligand may be a thiol compound such as methane thiol, ethane thiol, propane thiol, butane thiol, pentane thiol, hexane thiol, octane thiol, dodecane thiol, hexadecane thiol, octadecane thiol, or benzyl thiol; methanoic acid, ethanoic acid, propanoic acid; a phosphine compound such as methyl phosphine, ethyl phosphine, propyl phosphine, butyl phosphine, pentyl phosphine, octyl phosphine, dioctyl phosphine, tributyl phosphine, or trioctyl phosphine; a phosphine oxide compound such as methyl phosphine oxide, ethyl phosphine oxide, propyl phosphine oxide, butyl phosphine oxide pentyl phosphine oxide, tributyl phosphine oxide, octyl phosphine oxide, dioctyl phosphine oxide, or trioctyl phosphine oxide; a diphenyl phosphine, a triphenyl phosphine compound, or an oxide compound thereof; C5 to C20 alkyl phosphonic acid or phosphinic acid such as hexyl phosphinic acid, octyl phosphinic acid, dodecane phosphinic acid, tetradecane phosphinic acid, hexadecane phosphinic acid, octadecane phosphinic acid; and the like, but are not limited thereto.

A content of the first ligand of the quantum dots in the first light emitting layer 13a may be greater than or equal to about 1 wt %, greater than or equal to about 2 wt %, greater than or equal to about 3 wt %, greater than or equal to about 4 wt %, or greater than or equal to about 5 wt %, and less than or equal to about 60 wt %, less than or equal to about 50 wt %, less than or equal to about 40 wt %, or less than or equal to about 30 wt % based on a total amount (100 wt %) of ligand of the quantum dots in the first light emitting layer. The energy level of the first light emitting layer 13a can be easily adjusted within the above range.

A content of the second ligand of the quantum dots in the second light emitting layer 13b may be greater than or equal to about 1 wt %, greater than or equal to about 2 wt %, greater than or equal to about 3 wt %, greater than or equal to about 4 wt %, or greater than or equal to about 5 wt % and less than or equal to about 60 wt %, less than or equal to about 50 wt %, less than or equal to about 40 wt %, or less than or equal to about 30 wt % based on a total amount (100 wt %) of the ligand of the quantum dots in the second light emitting layer. The energy level of the second light emitting layer 13b can be easily adjusted within the above range.

The content of ligands of the quantum dots of the first and second light emitting layers 13a and 13b may be for example confirmed by scanning or transmission electron microscope energy dispersive X-ray spectroscopy (e.g., SEM-EDX), and the like, but is not limited thereto.

In addition, each thickness of the first light emitting layer 13a and the second light emitting layer 13b may be the same or different, and may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to about 20 nm, greater than or equal to about 25 nm, or greater than or equal to about 30 nm. In addition, each thickness of the first light emitting layer 13a and the second light emitting layer 13b may be less than or equal to about 50 nm, less than or equal to about 40 nm, less than or equal to about 30 nm, or less than or equal to about 20 nm. In an embodiment, each thickness of the first light emitting layer 13a and second light emitting layer 13b may be 1 monolayer or more (e.g., 2 monolayers) consisting of quantum dots, but is not limited thereto.

The light emitting layer 13 may have a thickness of greater than or equal to about 10 nm, for example, greater than or equal to about 15 nm, greater than or equal to about 20 nm, or greater than or equal to about 30 nm, and less than or equal to about 100 nm, for example, less than or equal to about 90 nm, less than or equal to about 80 nm, less than or equal to about 70 nm, less than or equal to about 60 nm, or less than or equal to about 50 nm. The light emitting layer 13 may have a thickness, for example about 10 nm to about 100 nm, for example about 10 nm to about 90 nm, for example about 10 nm to about 80 nm.

In the light emitting layer 13, the quantum dots may control an absorption/emission wavelength by adjusting a composition and a size of the quantum dots. A maximum peak emission wavelength of the quantum dot may be an ultraviolet (UV) to infrared wavelength or a wavelength of greater than the above wavelength range. For example, the maximum peak emission wavelength of the quantum dot may be greater than or equal to about 300 nm, for example, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The maximum peak emission wavelength of the quantum dot may be less than or equal to about 800 nm, for example, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The maximum peak emission wavelength of the quantum dots may be in the range of about 500 nm to about 650 nm. The maximum peak emission wavelength of the quantum dots may be in the range of about 500 nm to about 550 nm (green). The maximum peak emission wavelength of the quantum dots may be in the range of about 600 nm to about 650 nm (red).

The first and second light emitting layers 13a and 13b may be configured to emit light of the same color. Herein, each of quantum dots included in the first and second light emitting layers 13a and 13b may have a difference of central wavelength of less than or equal to about 15 nm at maximum, for example, for example, less than or equal to about 10 nm. In this case, light (e.g., electroluminescence peak) emitted from the first and second light emitting layers 13a and 13b may have a full width at half maximum (FWHM) of less than or equal to about 60 nm, less than or equal to about 50 nm, less than or equal to about 40 nm, less than or equal to about 35 nm, less than or equal to about 30 nm, less than or equal to about 25 nm, or less than or equal to about 20 nm.

Alternatively, in the light emitting layer 13, the first and second light emitting layers 13a and 13b may be configured to emit light of different colors from each other.

The quantum dots may have (electroluminescence or photoluminescence) quantum efficiency of greater than or equal to about 10%, for example, greater than or equal to about 30%, greater than or equal to about 50%, greater than or equal to about 60%, greater than or equal to about 70%, greater than or equal to about 90%, or even about 100%. The quantum dots may have a relatively narrow emission spectrum. A (electro- or photo-) emission spectrum of the quantum dots may have for example a full width at half maximum (FWHM) of less than or equal to about 50 nm, for example less than or equal to about 45 nm, less than or equal to about 40 nm, less than or equal to about 35 nm, or less than or equal to about 30 nm.

The light emitting device 10 may further include a third light emitting layer (not shown) between the first light emitting layer 13a and the second light emitting layer 13b, and the HOMO energy level of the third light emitting layer may be between the HOMO energy level of the first light emitting layer 13a and the HOMO energy level of the second light emitting layer 13b.

The light emitting device 10 may include a first charge auxiliary layer 12 between the light emitting layer 13 and the first electrode 11, and a second charge auxiliary layer 14 between the light emitting layer 13 and the second electrode 15. The HOMO energy levels of each layer of the first charge auxiliary layer 12, the first light emitting layer 13a, the second light emitting layer 13b, and the second charge auxiliary layer 14 may sequentially become larger (deeper).

A difference between the HOMO energy level of each layer and the HOMO energy level of the adjacent layer may be greater than or equal to about 0.1 eV, for example, greater than about 0.1 eV, greater than or equal to about 0.2 eV, greater than or equal to about 0.3 eV, greater than or equal to about 0.4 eV, greater than or equal to about 0.5 eV, greater than or equal to about 0.6 eV, greater than or equal to about 0.7 eV, greater than or equal to about 0.8 eV, greater than or equal to about 0.9 eV, or greater than or equal to about 1.0 eV and less than or equal to about 1.5 eV, for example less than or equal to about 1.4 eV, less than or equal to about 1.3 eV, or less than or equal to about 1.2 eV.

The first charge auxiliary layer 12 between the light emitting layer 13 and the first electrode 11 may have one layer or two or more layers and may include, for example a hole injection layer, a hole transport layer, and/or an electron blocking layer.

The first charge auxiliary layer (hole auxiliary layer) 12 may have a lower (shallower) HOMO energy level than the HOMO energy level of the first light emitting layer 13a, and thus the mobility of holes transferred from the first charge auxiliary layer 12 to the first light emitting layer 13a may be enhanced.

For example, a difference between the HOMO energy levels of the first charge auxiliary layer 12 and the first emitting layer 13a may be greater than or equal to about 0.1 eV, for example greater than about 0.1 eV, greater than or equal to about 0.2 eV, greater than or equal to about 0.3 eV, greater than or equal to about 0.4 eV, greater than or equal to about 0.5 eV, greater than or equal to about 0.6 eV, greater than or equal to about 0.7 eV, greater than or equal to about 0.8 eV, greater than or equal to about 0.9 eV, or greater than or equal to about 1.0 eV. Additionally, the difference in HOMO energy levels between the first charge auxiliary layer 12 and the first light emitting layer 13a may be less than or equal to about 1.5 eV, for example less than or equal to about 1.4 eV, less than or equal to about 1.3 eV, or less than or equal to about 1.2 eV.

In an embodiment, the first charge auxiliary layer 12 may include a hole injection layer proximate to the first electrode 11 and a hole transport layer proximate to the first light emitting layer 13a. At this time, the HOMO energy level of the hole injection layer may be lower (shallower) than the HOMO energy level of the hole transport layer.

A material included in the first charge auxiliary layer 12 (e.g., hole transport layer or hole injection layer) is not particularly limited and may include for example at least one selected from poly(9,9-dioctyl-fluorene-co-N-(4-butylphenyl)-diphenylamine) (TFB), polyarylamine, poly(N-vinylcarbazole) (PVK), poly(3,4-ethylenedioxythiophene) (PEDOT), poly(3,4-ethylenedioxythiophene):polystyrene sulfonate (PEDOT:PSS), polyaniline, polypyrrole, N,N,N′,N′-tetrakis(4-methoxyphenyl)-benzidine (TPD), 4-bis[N-(1-naphthyl)-N-phenyl-amino]biphenyl (α-NPD), m-MTDATA (4,4′,4″-tris[phenyl(m-tolyl)amino]triphenylamine), 4,4′,4″-tris(N-carbazolyl)-triphenylamine (TCTA), 1,1-bis[(di-4-tolyl amino)phenyl]cyclohexane (TAPC), dipyrazino[2,3-f:2′,3′-h]quinoxaline-2,3,6,7,10,11-hexacarbonitrile (HAT-CN), a p-type metal oxide (e.g., NiO, WO₃, MoO₃, etc.), a carbon-based material such as graphene oxide, and a combination thereof, but is not limited thereto.

In a first charge auxiliary layer (hole auxiliary layer) 12, a thickness of each layer may be appropriately selected. For example, the thickness of each layer may be greater than or equal to about 10 nm, for example, greater than or equal to about 15 nm, or greater than or equal to about 20 nm and less than or equal to about 100 nm, for example, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

The second charge auxiliary layer (electron auxiliary layer) 14 is disposed between the second light emitting layer 13b and the second electrode (e.g., cathode) 15. The second charge auxiliary layer 14 may include, for example an electron injection layer, an electron transport layer, and/or a hole blocking layer, but is not limited thereto. In an embodiment, the second charge auxiliary layer 14 may include an electron transport layer.

The HOMO energy level of the second charge auxiliary layer (electron auxiliary layer) 14 may have a higher (deeper) HOMO energy level than the HOMO energy level of the second light emitting layer 13b, and the mobility of electrons transferred from the second charge auxiliary layer 14 to the second light emitting layer 13b may be enhanced.

For example, a difference between the HOMO energy levels of the second charge auxiliary layer 14 and the second light emitting layer 13b may be greater than or equal to about 0.1 eV, for example greater than about 0.1 eV, greater than or equal to about 0.2 eV, greater than or equal to about 0.3 eV, greater than or equal to about 0.4 eV, greater than or equal to about 0.5 eV, greater than or equal to about 0.6 eV, greater than or equal to about 0.7 eV, greater than or equal to about 0.8 eV, greater than or equal to about 0.9 eV, or greater than or equal to about 1.0 eV. Additionally, the difference in HOMO energy levels between the second charge auxiliary layer 14 and the second light emitting layer 13b may be less than or equal to about 1.5 eV, for example, less than or equal to about 1.4 eV, less than or equal to about 1.3 eV, or less than or equal to about 1.2 eV.

The electron transport layer and/or the electron injection layer may include for example at least one of 1,4,5,8-naphthalene-tetracarboxylic dianhydride (NTCDA), bathocuproine (BCP), tris[3-(3-pyridyl)-mesityl]borane (3TPYMB), LiF, Alq₃, Gaq₃, Inq₃, Znq₂, Zn(BTZ)₂, BeBq₂, ET204 (8-(4-(4,6-di(naphthalen-2-yl)-1,3,5-triazin-2-yl)phenyl)quinolone), 8-hydroxyquinolinato lithium (Liq), n-type metal oxide (e.g., ZnO, HfO₂, etc.), and a combination thereof, but is not limited thereto. The hole blocking layer may include for example at least one of 1,4,5,8-naphthalene-tetracarboxylic dianhydride (NTCDA), bathocuproine (BCP), tris[3-(3-pyridyl)-mesityl]borane (3TPYMB), LiF, Alq₃, Gaq₃, Inq₃, Znq₂, Zn(BTZ)₂, BeBq₂, and a combination thereof, but is not limited thereto.

In an embodiment, the second charge auxiliary layer 14 (e.g., electron transport layer) may include a plurality of nanoparticles. The nanoparticles include a metal oxide including zinc.

The metal oxide may include Zn₁₋ₓMₓO (wherein M is Mg, Ca, Zr, W, Li, Ti, or a combination thereof and 0≤x≤0.5). In an embodiment, the M may be magnesium (Mg). In an embodiment, in Zn₁₋ₓMₓO, x may be greater than or equal to about 0.01 and less than or equal to about 0.3, for example, less than or equal to about 0.25, less than or equal to about 0.2, or less than or equal to about 0.15.

An average size of the nanoparticles may be greater than or equal to about 1 nm, for example, greater than or equal to about 1.5 nm, greater than or equal to about 2 nm, greater than or equal to about 2.5 nm, or greater than or equal to about 3 nm and less than or equal to about 10 nm, less than or equal to about 9 nm, less than or equal to about 8 nm, less than or equal to about 7 nm, less than or equal to about 6 nm, or less than or equal to about 5 nm. The nanoparticles may not have a rod shape. The nanoparticles may not have a nano wire shape.

In an embodiment, a thickness of the second charge auxiliary layer 14 (e.g., including an electron injection layer, an electron transport layer, or a hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

As described above, the light emitting device 10 may include a first charge auxiliary layer between the first light emitting layer 13a and the first electrode and a second charge auxiliary layer between the light emitting layer and the second electrode. The HOMO energy levels of each of the first charge auxiliary layer, the first light emitting layer, the second light emitting layer, and the second charge auxiliary layer may be sequentially increased in the order stated.

The light emitting device 10 may further include a substrate (not shown). The substrate may be disposed at the side of the first electrode 11 or the second electrode 15. In an embodiment, the substrate may be disposed at the side of the first electrode. The substrate may be a substrate including an insulation material (e.g., an insulating transparent substrate). The substrate may include glass; various polymers such as polyester (e.g., polyethyleneterephthalate (PET), polyethylenenaphthalate (PEN)), polycarbonate, polyacrylate, polyimide, and polyamideimide; polysiloxane (e.g. PDMS); inorganic materials such as Al₂O₃ and ZnO; or a combination thereof, but is not limited thereto. The substrate may be made of a silicon wafer, and the like. Herein, “transparent” refers to transmittance for light in a predetermined wavelength (e.g., light emitted from the quantum dots) of greater than or equal to about 85%, for example, greater than or equal to about 88%, greater than or equal to about 90%, greater than or equal to about 95%, greater than or equal to about 97%, or greater than or equal to about 99%. A thickness of the substrate may be appropriately selected considering a substrate material, and the like, but is not particularly limited. The transparent substrate may have flexibility. The substrate may be omitted.

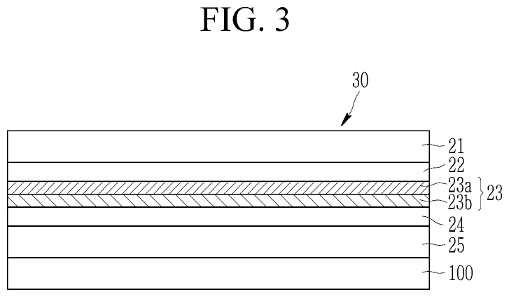

The structure of a light emitting device including the substrate is described referring to FIGS. 2 and 3.

FIG. 2 is a cross-sectional view schematically showing a light emitting device according to an embodiment having a normal structure. Referring to FIG. 2, a light emitting device 20 includes a first electrode (anode) 21 disposed on a transparent substrate 100 which may include a metal oxide-based transparent electrode (e.g., ITO electrode) and a second electrode 25 facing the first electrode 21 which may include a conductive metal (e.g., Mg, Al, and/or Ag, etc.) (e.g., having a relatively low work function). A first charge auxiliary layer 22 (e.g., a hole injection layer of PEDOT:PSS and/or p-type metal oxide, and the like and/or hole transport layer of TFB and/or PVK) may be disposed between the first electrode 21 and the light emitting layer 23. The hole injection layer may be proximate to the first electrode 21 and the hole transport layer may be proximate to the light emitting layer 23. A second charge auxiliary layer (an electron auxiliary layer) 24 such as an electron injection layer/electron transport layer, and the like may be disposed between the light emitting layer 23 and the second electrode 25. Like the light emitting layer 13 of FIG. 1, the light emitting layer 23 may include a first light emitting layer 23a and a second light emitting layer 23b which correspond to the first light emitting layer 13a and the second light emitting layer 13b.

FIG. 3 is a schematic cross-sectional view of a light emitting device according to an embodiment having an inverted structure. Referring to FIG. 3, a light emitting device 30 includes a second electrode 25 disposed on a transparent substrate 100 which may include a metal oxide-based transparent electrode (e.g., ITO) and a first electrode 21 facing the second electrode 25 which may include a metal (e.g., Au, Ag, Al, and/or Mg, etc.) (e.g., having a relatively high work function). For example, (optionally doped) n-type metal oxide (crystalline Zn metal oxide) may be disposed between the second electrode (transparent electrode) 25 and the light emitting layer 23 as a second charge auxiliary layer 24 (an electron auxiliary layer, for example, an electron transport layer). MoO₃ or other p-type metal oxides may be disposed between the first electrode (metal electrode) 21 and the light emitting layer 23 as a first charge auxiliary layer 22 (a hole auxiliary layer, for example, a hole transport layer including TFB and/or PVK, and/or a hole injection layer including PVK and/or MoO₃ or other p-type metal oxides). Like the light emitting layer 13 of FIG. 1, the light emitting layer 23 may include a first light emitting layer 23a and a second light emitting layer 23b which correspond to the first light emitting layer 13a and the second light emitting layer 13b.

Another embodiment provides a method of producing the aforementioned light emitting device. The producing method includes forming a first charge auxiliary layer on a first electrode; forming a light emitting layer on the first charge auxiliary layer; forming a first charge auxiliary layer on the light emitting layer; and forming a second electrode on the first charge auxiliary layer,
wherein, the forming of the light emitting layer includes
forming a first light emitting layer including a plurality of quantum dots having a first ligand on the surface; and
forming a second light emitting layer on the first light emitting layer including a plurality of quantum dots having a second ligand on the surface.

Details about the first electrode, first charge auxiliary layer, second charge auxiliary layer, first light emitting layer, second light emitting layer, and second electrode are as described above.

The forming of the first light emitting layer may be performed by dispersing the quantum dots having the first ligand in a solvent (e.g., an organic solvent) to obtain quantum dot dispersion and coating or depositing it on the first charge auxiliary layer in an appropriate manner (e.g., spin coating, inkjet printing, etc.). The forming of the first light emitting layer and the second light emitting layer may further include heat-treating the coated or deposited quantum dot layer. The heat-treating temperature is not particularly limited and may be appropriately selected considering a boiling point of the organic solvent. For example, the heat-treating temperature may be greater than or equal to about 60° C. The organic solvent of the quantum dot dispersion is not particularly limited and thus may be appropriately selected. In an embodiment, the organic solvent may include a (substituted or unsubstituted) aliphatic hydrocarbon organic solvent, a (substituted or unsubstituted) aromatic hydrocarbon organic solvent, an acetate solvent, or a combination thereof.

The quantum dots having the first ligand may be prepared by adding the first ligand during final synthesis, or may be prepared by substituting the first ligand for the ligand present in the quantum dots during synthesis.

The second light emitting layer may be prepared in the same manner as the first light emitting layer, except that quantum dots having the second ligand are dispersed in a solvent (e.g., an organic solvent) to form a quantum dot dispersion.

Alternatively, a first ligand-containing solution may be coated on a quantum dot layer prepared from a quantum dot dispersion (e.g., by spin coating, spray coating, etc.) to replace the ligand present in the quantum dot layer with the first ligand to form a first light emitting layer. The coating process may be performed one or more times, for example, two or more times, three or more times, or four or more times.

The first ligand-containing solution may be prepared by dissolving the first ligand in an alcohol solvent (e.g., C1 to C10 alcohol, such as methanol, ethanol, propanol, isopropanol, butanol, pentanol, hexanol, heptanol, etc.). A concentration of the first ligand (second ligand) in the alcohol solvent may be greater than or equal to about 0.001 g/L, for example, be greater than or equal to about 0.01 g/L, be greater than or equal to about 0.1 g/L, be greater than or equal to about 1 g/L, be greater than or equal to about 10 g/L, be greater than or equal to about 50 g/L, be greater than or equal to about 60 g/L, be greater than or equal to about 70 g/L, be greater than or equal to about 80 g/L, or be greater than or equal to about 90 g/L and less than or equal to about 1000 g/L, for example, less than or equal to about 500 g/L, less than or equal to about 400 g/L, less than or equal to about 300 g/L, less than or equal to about 200 g/L, less than or equal to about 100 g/L, less than or equal to about 90 g/L, less than or equal to about 80 g/L, less than or equal to about 70 g/L, less than or equal to about 60 g/L, less than or equal to about 50 g/L, less than or equal to about 40 g/L, less than or equal to about 30 g/L, less than or equal to about 20 g/L, or less than or equal to about 10 g/L, but is not limited thereto.

After coating the ligand-containing solution, a process of heating to a predetermined temperature may be performed.

The heating process may be performed at a temperature greater than or equal to about 30° C., greater than or equal to about 40° C., greater than or equal to about 50° C., greater than or equal to about 60° C., greater than or equal to about 70° C., greater than or equal to about 80° C., greater than or equal to about 90° C., or greater than or equal to about 100° C., and less than or equal to about 200° ° C., less than or equal to about 190° C., less than or equal to about 180 ºC, less than or equal to about 170° C., less than or equal to about 160° C., less than or equal to about 150° C., less than or equal to about 140° C., less than or equal to about 130° C., less than or equal to about 120° C., less than or equal to about 110° C., less than or equal to about 100° C., or less than or equal to about 90° C.

The above method can be equally applied to forming the second emitting layer, except that the second ligand-containing solution is used instead of the first ligand-containing solution.

In general, it is not easy to form a thin film using multiple applications of coating dispersion of quantum dots including the same type of organic ligand. The reason is that a solvent in the quantum dot dispersion dissolves a previously coated quantum dot coating film. As a result, multiple applied coatings of the dispersion of quantum dots including the same type of organic ligand may not provide a quantum dot coating film having a desired thickness.

In the method according to an embodiment, the solubility/dispersibility of the quantum dots in the ligand-substituted layer changes significantly, so that the lower layer is not dissolved by the quantum dot dispersion used in the subsequent coating process. In other words, since the first and second light emitting layers have different ligand compositions, there is no problem of the quantum dots of the first light emitting layer dissolving during the forming (application coating) of the upper layer (for example, the second light emitting layer).

Another embodiment provides an electronic device including the aforementioned light emitting device.

The light emitting device may be applied to various electronic devices such as display devices or lighting devices.

The display device may include a first pixel and a second pixel configured to emit light of a different color from the first pixel. A light emitting device (e.g., electroluminescent device) according to an embodiment may be disposed in the first pixel, the second pixel, or a combination thereof. In an embodiment, the display device may include blue pixels, red pixels, green pixels, or a combination thereof. In the display device, the red pixel may include a red light emitting layer including a plurality of red light-emitting semiconductor nanoparticles, the green pixel may include a green light emitting layer including a plurality of green light-emitting semiconductor nanoparticles, and the blue pixel may include a blue light emitting layer including a plurality of blue light-emitting semiconductor nanoparticles.

Hereinafter, the embodiments are illustrated in more detail with reference to examples. However, these examples are exemplary, and the present scope is not limited thereto.

### Synthesis of Quantum Dots

### Synthesis Example 1-1: Synthesis of ZnSeTe/ZnSe/ZnS core-shell quantum dots (QD1)

[1] Selenium and tellurium are dispersed in trioctylphosphine (TOP) to obtain a Se/TOP stock solution and a Te/TOP stock solution.

In a reaction flask containing 400 mL of trioctylamine (TOA), oleic acid and oleylamine are heated to 120° C. under vacuum. After one hour, nitrogen is introduced into the reactor. The reactor is heated at 300° C., the prepared Se/TOP stock solution and Te/TOP stock solution are rapidly added in a mole ratio of Te:Se of 1:15. After completion of the reaction, the reactor is quickly cooled to room temperature and ethanol is added. A precipitate forms and is separated with a centrifuge. The resulting precipitate is dispersed in toluene to obtain a ZnSeTe core. The average size of the core is approximately 3 nm.

[2] Zinc acetate along with oleic acid is added to a reaction flask including 80 ml of TOA and vacuum-treated at 120° C. Nitrogen is introduced into the reaction flask, the temperature of the flask raised to 200° C., and the toluene dispersion of the prepared ZnSeTe core is quickly added to the reaction flask at a temperature of approximately 200° ° C. The Se/TOP stock solution is added intermittently in three portions and reacted for 30 minutes to form a ZnSe shell layer on the ZnSeTe core.

[3] Sulfur is dispersed in TOP to obtain a S/TOP stock solution and the S/TOP stock solution along with zinc acetate is added intermittently in three portions to the reaction flask and reacted for 20 minutes to form a ZnS second shell layer to prepare a quantum dot dispersion.

The contents of Zn precursor (zinc acetate), Se, S, and Te used are 26.4 mmol, 12 mmol, 22.4 mmol, and 0.8 mmol, respectively.

### Synthesis Example 1-2: Synthesis of ZnSeTe/ZnSe/ZnS core-shell quantum dots (QD2)

Steps [1] and [2] of Synthesis Example 1-1 are repeated. Then a S/TOP stock solution along with zinc acetate is added intermittently in two portions to the reaction flask and reacted for 20 minutes to form a ZnS second shell layer, and provide a quantum dot dispersion.

The contents of Zn precursor (zinc acetate), Se, S, and Te used are 26.4 mmol, 12 mmol, 22.4 mmol, and 0.8 mmol, respectively. When forming the second ZnS shell layer, 1.6 mmol of PFOA (perfluorooctanoic acid) is added and reacted.

### Synthesis Example 1-3: Synthesis of ZnSeTe/ZnSe/ZnS core-shell quantum dots (QD3)

Steps [1] and [2] of Synthesis Example 1-1 are repeated. Then, a S/TOP stock solution along with zinc acetate is added intermittently in two portions to the reaction flask and reacted for 20 minutes to form a ZnS second shell layer, and provide a quantum dot dispersion.

The contents of Zn precursor (zinc acetate), Se, S, and Te used are 26.4 mmol, 12 mmol, 22.4 mmol, and 0.8 mmol, respectively. When forming the second ZnS shell layer, 3.2 mmol of PFOA (Perfluorooctanoic acid) is added and reacted.

### Synthesis Example 1-4: Synthesis of ZnSeTe/ZnSe/ZnS core-shell quantum dots (QD4)

Steps [1] and [2] of Synthesis Example 1-1 are repeated. Then, a S/TOP stock solution along with zinc acetate is added intermittently in two portions to the reaction flask and reacted for 20 minutes to form a ZnS second shell layer and provide a quantum dot dispersion.

The contents of Zn precursor (zinc acetate), Se, S, and Te used are 26.4 mmol, 12 mmol, 22.4 mmol, and 0.8 mmol, respectively. When forming the second ZnS shell layer, 1.2 mmol of 4-chloro benzoic acid is added and reacted.

### Synthesis of Metal Oxide Nanoparticles

### Synthesis Example 2: Synthesis of Zn Metal Oxide Nanoparticles

Zinc acetate dihydrate and magnesium acetate tetrahydrate are added to dimethyl sulfoxide in a reactor so that a mole ratio of the following chemical formula below is provided, and the reactor is heated at 60° C. in air. Subsequently, an ethanol solution of tetramethylammonium hydroxide pentahydrate is added in a dropwise fashion to the reactor at a rate of 3 mL/min. The obtained mixture is stirred for one hour, and ZnₓMg₁₋ₓO nanoparticles produced are separated with a centrifuge and dispersed in ethanol to obtain ZnₓMg₁₋ₓO nanoparticles (x=0.85).

The obtained nanoparticles are analyzed with an X-ray diffraction analysis to confirm that ZnO crystals are formed. A transmission electron microscopic analysis is also performed of the obtained nanoparticles and the results show that the ZnₓMg₁₋ₓO nanoparticles have an average size of about 3 nm.

Energy bandgaps of the obtained nanoparticles are measured and monitored by a UV band edge tangent line (UV-2600, SHIMADZU). As a result, the HOMO energy level of the synthesized ZnxMg1-xO nanoparticles is −7.6 eV and the LUMO energy level is −4.2 eV.

Manufacture of Light Emitting layer

### Manufacture of Light Emitting Layer 1-1 (First Light Emitting Layer)

The core/shell quantum dots dispersion in which the core/shell quantum dots obtained in Synthesis Example 1-1 are separated from the toluene dispersion and are dispersed in cyclohexane is spin-coated on a silicon substrate and heat-treated at 80° C. for 30 minutes to form light emitting layer 1-1 (first light emitting layer).

### Examples: Manufacture of Light Emitting Layers 1-2 to 1-4 (Second Light Emitting Layer)

Each dispersion in which the core/shell quantum dots obtained in Synthesis Examples 1-2, 1-3, and 1-4 are separated from the toluene dispersion and are dispersed in cyclohexane is spin-coated on a silicon substrate, and heat-treated at 80° C. for 30 minutes to form light emitting layers 1-2, 1-3, and 1-4 (second light emitting layer).

### Evaluation 1: Evaluation of Energy Level of Light Emitting Layer

The energy levels of the 30 nm-thick thin films formed by spin coating each of the core-shell quantum dots according to Synthesis Examples 1-1 to 1-4 on a glass substrate are obtained. HOMO energy levels are evaluated with an amount of photoelectrons emitted by energy when irradiating UV light to a thin film using AC-2 (Hitachi) or AC-3 (Riken Keiki Co., Ltd.). Energy bandgaps are obtained by using a UV-Vis spectrometer (Shimadzu Corp.). The LUMO energy levels are calculated by using the energy bandgaps and the HOMO energy levels. The results are shown in Table 1.

TABLE 1

| | | | Energy |
|---|---|---|---|
| | HOMO (eV) | LUMO (eV) | bandgap (eV) |
| Synthesis Example 1-1 | −5.62 | −2.92 | 2.7 |
| Synthesis Example 1-2 | −6.06 | −3.36 | 2.7 |
| Synthesis Example 1-3 | −5.86 | −3.16 | 2.7 |
| Synthesis Example 1-4 | −6.15 | −3.45 | 2.7 |

Referring to Table 1, the light emitting layers including quantum dots of Synthesis Example 1-1 to Synthesis Example 1-4 have different energy levels.

### Example 1: Manufacture of EOD (Electron Only Device)

After performing surface treatment with UV-ozone for 15 minutes on the glass substrate on which ITO is deposited, the quantum dot dispersion obtained in Synthesis Example 1-1 is spin-coated to form a first light emitting layer with a thickness of 20 nm. The quantum dot dispersion obtained in Synthesis Example 1-2 is spin-coated on the first light emitting layer to form a second light emitting layer with a thickness of 20 nm.

The dispersion obtained by dispersing the zinc magnesium oxide nanoparticles prepared in Synthesis Example 2 in ethanol is spin-coated on the second light emitting layer and heat-treated at 80° C. to form an electronic auxiliary layer (thickness: 20 nm). A cathode is formed by vacuum depositing 100 nm of aluminum (Al) on the obtained electronic auxiliary layer to manufacture the electron only device according to Example 1.

### Example 2: Manufacture of EOD (Electron Only Device)

The electron only device according to Example 2 is manufactured in the same manner as Example 1, except that the quantum dot dispersion obtained in Synthesis Example 1-3 is used when manufacturing the second light emitting layer.

### Example 3: Manufacture of EOD (Electron Only Device)

The electron only device according to Example 3 is manufactured in the same manner as Example 1, except that the quantum dot dispersion obtained in Synthesis Example 1-4 is used when manufacturing the second light emitting layer.

### Comparative Example 1: Manufacture of EOD (Electron Only Device)

After performing surface treatment with UV-ozone for 15 minutes on the glass substrate on which ITO is deposited, the quantum dot dispersion obtained in Synthesis Example 1-1 is spin coated to form a 30 nm-thick light emitting layer.

The dispersion obtained by dispersing the zinc magnesium oxide nanoparticles prepared in Synthesis Example 2 in ethanol is spin-coated on the light emitting layer and heat-treated at 80° ° C. to form an electronic auxiliary layer (thickness: 20 nm). A cathode is formed by vacuum depositing 100 nm of aluminum (Al) on the obtained electronic auxiliary layer to manufacture the electron only device according to Comparative Example 1.

### Comparative Example 2: Manufacture of EOD (Electron Only Device)

After performing surface treatment with UV-ozone for 15 minutes on the glass substrate on which ITO is deposited, the quantum dot dispersion obtained in Synthesis Example 1-2 is spin coated to form a 20 nm-thick light emitting layer.

The quantum dot dispersion obtained in Synthesis Example 1-1 is spin-coated on the first light emitting layer to form a second light emitting layer with a thickness of 20 nm.

The dispersion obtained by dispersing the zinc magnesium oxide nanoparticles prepared in Synthesis Example 2 in ethanol is spin-coated on the second light emitting layer and heat-treated at 80° C. to form an electronic auxiliary layer (thickness: 20 nm).

A cathode is formed by vacuum depositing 100 nm of aluminum (Al) on the obtained electronic auxiliary layer to manufacture the electron only device according to Comparative Example 2.

### Evaluation 2: Electroluminescence Properties of Devices

The electroluminescence properties (external quantum efficiency (EQE), luminance, life-span characteristics, driving voltage, and voltage stability (ΔV/hr)) of the EOD devices according to Example 1, Example 2, Comparative Example 1, and Comparative Example 2 are evaluated.

The electroluminescence properties are evaluated by applying a voltage to the EOD devices and measuring the current according to the voltage using a Keithley 2200 source measuring device and a Minolta CS2000 spectroradiometer (current-voltage-luminance measuring device).

When driven at a given luminance (e.g., 650 nit and 280 nit), the time (hr, T50) it takes for the initial luminance of 100% to become 50% luminance is measured.

The voltage stability is evaluated by measuring the changes in voltage values that change per hour.

The results are shown in Table 2.

TABLE 2

| | EQE | Lum. | T50(hr) | T50(hr) | Initial | |
|---|---|---|---|---|---|---|
| | (%) | (nit) | @650 nit | @280 nit | (V) | ΔV/hr |
| Example 1 | 7.4 | 96700 | 271.3 | 1235.3 | 2.7 | 0.0054 |
| Example 2 | 8.7 | 98926 | 308.7 | 1405.63 | 2.9 | 0.0031 |
| Comparative | 5 | 72603 | 143.5 | 653.4 | 3.1 | 0.0152 |
| Example 1 | | | | | | |
| Comparative | 6 | 105992 | 237.6 | 1081.76 | 3.2 | 0.0049 |
| Example 2 | | | | | | |

Referring to Table 2, the device according to Example 1 has improved external quantum efficiency, luminance, life-span characteristics, and voltage stability and a lower driving voltage compared to Comparative Example 1.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A light emitting device, comprising
a first electrode and a second electrode facing each other, and a light emitting layer disposed between the first electrode and the second electrode, the light emitting layer comprising quantum dots,
wherein the light emitting layer comprises a first light emitting layer proximate to the first electrode, and a second light emitting layer proximate to the second electrode,
the quantum dots of the first light emitting layer include a first ligand on a surface of the quantum dots, and the quantum dots of the second light emitting layer include a second ligand on a surface of the quantum dots, wherein the first ligand is different from the second ligand, and
a HOMO energy level of the first light emitting layer is lower (shallower) than a HOMO energy level of the second light emitting layer.

2. The light emitting device of claim 1, wherein
a difference between the HOMO energy level of the first light emitting layer and the HOMO energy level of the second light emitting layer is greater than or equal to about 0.1 eV.

3. The light emitting device of claim 1, wherein
a LUMO energy level of the first light emitting layer is lower than a LUMO energy level of the second light emitting layer.

4. The light emitting device of claim 1, wherein
the first ligand comprises an amine ligand, an amide ligand, an alkoxide ligand, a carboxylic acid ligand, or a combination thereof, and
the second ligand comprises a halogen-substituted carboxylic acid ligand, a halogen-substituted carboxylic acid ester ligand, a haloalkane ligand, a halogen ligand, or a combination thereof.

5. The light emitting device of claim 4, wherein
the amine ligand comprises a compound represented by Chemical Formula 1: 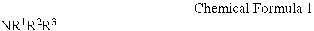
wherein, in Chemical Formula 1, R¹, R² and R³ are each independently hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C6 to C40 aryl group, a substituted or unsubstituted C3 to C40 heteroaryl group, or a combination thereof, or any two of R¹, R², or R³ are linked to each other to form an N-containing heterocycles, and R¹, R², and R³ are not all hydrogen or deuterium.

6. The light emitting device of claim 4, wherein
the amide ligand comprises a compound represented by Chemical Formula 2: 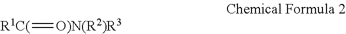
wherein, in Chemical Formula 2, R¹ and R³ are each independently hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C6 to C40 aryl group, a substituted or unsubstituted C3 to C40 heteroaryl group, or a combination thereof, and
R² is hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C6 to C40 aryl group, a substituted or unsubstituted C3 to C40 heteroaryl group, or a combination thereof.

7. The light emitting device of claim 4, wherein
the carboxylic acid ligand comprises a compound represented by Chemical Formula 3: 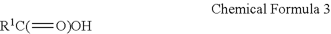
wherein, in Chemical Formula 3, R¹ is a substituted or unsubstituted C1 to C30 alkyl group, a substituted or unsubstituted C2 to C30 alkenyl group, a substituted or unsubstituted C2 to C30 alkynyl group, a substituted or unsubstituted C6 to C40 aryl group, a substituted or unsubstituted C3 to C40 heteroaryl group, or a combination thereof.

8. The light emitting device of claim 4, wherein
the halogen-substituted carboxylic acid ligand comprises a compound represented by Chemical Formula 4: 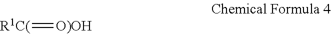
wherein, in Chemical Formula 4,
R¹ is a substituted or unsubstituted C1 to C30 haloalkyl group, a substituted or unsubstituted C2 to C30 haloalkenyl group, a substituted or unsubstituted C2 to C30 haloalkynyl group, a substituted or unsubstituted C6 to C40 halogen-substituted aryl group, a substituted or unsubstituted C3 to C40 halogen-substituted heteroaryl group, or a combination thereof.

9. The light emitting device of claim 8, wherein
the halogen-substituted carboxylic acid ligand is a perfluoroalkanoic acid ligand.

10. The light emitting device of claim 4, wherein
the halogen-substituted carboxylate ester ligand comprises a compound represented by Chemical Formula 5: 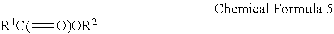
wherein, in Chemical Formula 5,
R¹ and R² are each independently a substituted or unsubstituted C1 to C30 haloalkyl group, a substituted or unsubstituted C2 to C30 haloalkenyl group, a substituted or unsubstituted C2 to C30 haloalkynyl group, a substituted or unsubstituted C6 to C40 halogen-substituted aryl group, a substituted or unsubstituted C3 to C40 halogen-substituted heteroaryl group, or a combination thereof.

11. The light emitting device of claim 10, wherein
the halogen-substituted carboxylate ester ligand is perfluoroalkanoic acid ester.

12. The light emitting device of claim 1, wherein
the first ligand comprises a chloro-substituted or unsubstituted carboxylic acid ligand, a chloro-substituted or unsubstituted carboxylic acid ester ligand, a chloroalkane ligand, a chloride ligand, or a combination thereof, and
the second ligand comprises a fluoro-substituted carboxylic acid ligand, a fluoro-substituted carboxylic acid ester ligand, a fluoroalkane ligand, a fluoride ligand, or a combination thereof.

13. The light emitting device of claim 1, wherein
the quantum dots of the first light emitting layer further includes a first organic ligand in addition to the first ligand, and the quantum dots of the second light emitting layer further includes a second organic ligand in addition to the second ligand,
a content of the first ligand of the quantum dots in the first light emitting layer is in a range of about 1 weight percent to about 60 weight percent based on a total amount (100 weight percent) of total ligand of the quantum dots in the first light emitting layer, and
a content of the second ligand of the quantum dots in the second light emitting layer is in a range of about 1 weight percent to about 60 weight percent based on a total amount (100 weight percent) of total ligand of the quantum dots in the second light emitting layer.

14. The light emitting device of claim 1, wherein
the light emitting layer further comprises a third light emitting layer between the first light emitting layer and the second light emitting layer, and the HOMO energy level of the third light emitting layer is between the HOMO energy level of the first light emitting layer and the HOMO energy level of the second light emitting layer.

15. The light emitting device of claim 1, wherein
the light emitting device comprises a first charge auxiliary layer between the light emitting layer and the first electrode, and a second charge auxiliary layer between the light emitting layer and the second electrode, and
the HOMO energy levels of each layer of the first charge auxiliary layer, the first light emitting layer, the second light emitting layer, and the second charge auxiliary layer sequentially increases from the first charge auxiliary layer to the second charge auxiliary layer.

16. The light emitting device of claim 1, wherein
the quantum dots of the first light emitting layer and the quantum dots of the second light emitting layer emit light of the same color, and a difference of peak emission wavelength of the quantum dots of the first and second light emitting layers is less than or equal to about 15 nm, and
the peak emission wavelength of the quantum dots of the first and second light emitting layers have a full width at half maximum of less than or equal to about 40 nm.

17. The light emitting device of claim 1, wherein
the quantum dots of the light emitting layer do not include a heavy metal.

18. The light emitting device of claim 13, wherein
the first organic ligand and the second organic ligand are each independently RSH, R₃PO, R₃P, ROH, RCOOR, RPO(OH)₂, RHPOOH, R₂POOH, or a combination thereof, wherein R is each independently a substituted or unsubstituted C1 to C40 aliphatic hydrocarbon group, a substituted or unsubstituted C6 to C40 aromatic hydrocarbon group, or a combination thereof.

19. The light emitting device of claim 15, wherein
the second charge auxiliary layer comprises a nanoparticle including a metal oxide.

20. A display device comprising the light emitting device of claim 1.
